(19) United States
(12) Patent Application Publication
(10) Pub. No.: US 2026/0271468 A1
(43) Pub. Date: Sep. 10, 2026

(54) LIGHT EMITTING DEVICE, DISPLAY APPARATUS, PHOTOELECTRIC CONVERSION APPARATUS, ELECTRONIC EQUIPMENT AND WEARABLE DEVICE

(71) Applicant: CANON KABUSHIKI KAISHA, Tokyo (JP)

(72) Inventors: HIDEMASA OSHIGE, Kanagawa (JP); AKIRA OKITA, Kanagawa (JP)

(21) Appl. No.: 19/555,295

(22) Filed: Mar. 3, 2026

(30) Foreign Application Priority Data
Mar. 5, 2025 (JP) 2025-034432

(51) Int. Cl. H10H 29/855; H10K 59/65; H10K 59/80

(52) U.S. Cl. CPC H10H 29/855; H10K 59/65; H10K 59/879

(57) ABSTRACT

A light-emitting device includes a display substrate having a principal surface including a display area on which a display element is disposed and a peripheral region on which an infrared-emitting element and an infrared-receiving element are disposed, and a light-transmitting substrate facing the principal surface, wherein the light-transmitting substrate includes a first area overlapping the display area and a second area overlapping the peripheral region in an orthogonal projection onto the principal surface, and wherein a lens structure is provided on each of an overlap area of the second area of the light-transmitting substrate that overlaps the infrared-emitting element and an overlap area of the second area of the light-transmitting substrate that overlaps the infrared-receiving element.

### BACKGROUND

### Field of the Technology

The present disclosure relates to a light-emitting device and a display apparatus, a photoelectric conversion apparatus, an electronic equipment, and a wearable device that use the light-emitting device.

### Description of the Related Art

An organic light-emitting element (also referred to as an organic electroluminescence (EL) element) includes a first electrode, a second electrode, and an organic compound layer between the two electrodes. Light generated by a light-emitting layer included in the organic compound layer exits through one of the first and second electrodes (light-extraction electrode). A light-emitting device including the organic light-emitting element may be used in a viewfinder of a camera or a wearable device, also referred to as a head-mounted display or smart glasses. Such a light-emitting device may be configured so that a gaze of a user is detected and the detected gaze information is used to drive the light-emitting device. Japanese Patent Laid-Open No. 2021-015731 discusses a light-emitting device in which an infrared-emitting element configured to emit infrared light and a light-receiving element configured to detect reflected light from an eyeball of a user are disposed on a display substrate provided with an organic light-emitting element. Japanese Patent Laid-Open No. 2016-225378 discusses a light-receiving/emitting element module in which a lens member is disposed above a semiconductor substrate provided with a light-emitting element and light-receiving element.

Japanese Patent Laid-Open No. 2021-015731 discusses disposing that the infrared-emitting element and the light-receiving element near the organic light-emitting element and disposing an opposing substrate to cover the display substrate. Light emitted by the infrared-emitting element exhibits maximum intensity at a front thereof. However, the eyeball of the user is normally in front of the organic light-emitting element and offset from the front of the infrared-emitting element. Thus, it is difficult to efficiently irradiate the eyeball of the user with light emitted by the infrared-emitting element. Similarly, reflected light from the eyeball of the user cannot be efficiently guided into the light-receiving element. Further, the light emitted by the infrared-emitting element and the reflected light from the eyeball of the user are partly absorbed while passing through the opposing substrate. This may decrease photo-receiving sensitivity to infrared light.

### SUMMARY

The present disclosure provides a technique that is effective in suppressing a decrease in photo-receiving sensitivity to infrared light in a light-emitting device including a system configured to detect a gaze of a user using an infrared-emitting element and a light-receiving element.

An aspect of the present disclosure provides a light-emitting device that includes a display substrate having a surface including a display area on which a display element is disposed and a peripheral region on which an infrared-emitting element and an infrared-receiving element are disposed, and a light-transmitting substrate facing the surface. The light-transmitting substrate includes a first area overlapping the display area and a second area overlapping the peripheral region in an orthogonal projection onto the surface. A lens structure is provided on each of an overlap area of the second area of the light-transmitting substrate that overlaps the infrared-emitting element and an overlap area of the second area of the light-transmitting substrate that overlaps the infrared-receiving element.

Features of the present disclosure will become apparent from the following description of embodiments with reference to the attached drawings. The following description of embodiments is provided as an example.

### BRIEF DESCRIPTION OF THE DRAWINGS

FIG. 1 is a perspective view illustrating a basic configuration of a light-emitting device and a gaze detection operation according to the present disclosure.

FIGS. 2A and 2B are a plan view and a cross-sectional view, respectively, schematically illustrating configurations of the light-emitting device according to an embodiment of the present disclosure.

FIG. 3 is a cross-sectional view schematically illustrating a configuration of a light-emitting device according to another embodiment of the present disclosure.

FIG. 4 is a cross-sectional view schematically illustrating a configuration of a light-emitting device according to another embodiment of the present disclosure.

FIG. 5A is a schematic cross-sectional view illustrating an example of a pixel of a display apparatus according to an embodiment of the present disclosure, and FIG. 5B is a schematic cross-sectional view illustrating an example of a display apparatus using an organic light-emitting element according to an embodiment of the present disclosure.

FIG. 6 is a schematic diagram illustrating an example of a display apparatus according to an embodiment of the present disclosure.

FIG. 7A is a schematic diagram illustrating an imaging apparatus according to an embodiment of the present disclosure, and FIG. 7B is a schematic diagram illustrating electronic equipment according to an embodiment of the present disclosure.

FIG. 8A is a schematic diagram illustrating a display apparatus according to an embodiment of the present disclosure, and FIG. 8B is a schematic diagram illustrating a foldable display apparatus according to an embodiment of the present disclosure.

FIG. 9A is a schematic diagram illustrating a lighting apparatus according to an embodiment of the present disclosure, and FIG. 9B is a schematic diagram illustrating an automobile including a vehicle lighting apparatus according to an embodiment of the present disclosure.

FIG. 10A is a schematic diagram illustrating a wearable device according to an embodiment of the present disclosure, and FIG. 10B is a schematic diagram illustrating an example of a wearable device including an imaging apparatus according to an embodiment of the present disclosure.

FIG. 11A is a schematic diagram illustrating an image forming apparatus according to an embodiment of the present disclosure, and FIGS. 11B and 11C are schematic diagrams illustrating a plurality of light-emitting portions of an exposure light source arranged on an elongated substrate.

### DESCRIPTION OF THE EMBODIMENTS

An embodiment will be described in detail below with reference to the attached drawings. The examples in the embodiments described below are not intended to limit the scope of the present disclosure. While the embodiment describes a plurality of features, the present disclosure does not require all of the features in the examples. Rather, the plurality of features may be combined. For conciseness, identical or similar components in the attached drawings are denoted by the same reference numerals, and redundant descriptions thereof are not repeated.

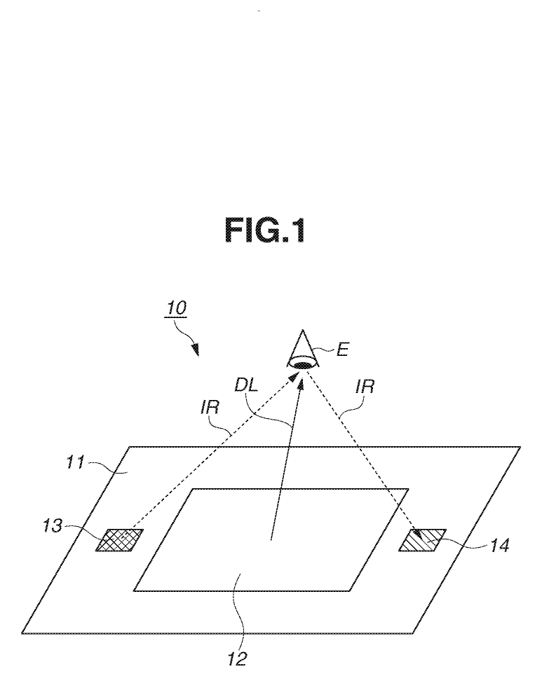

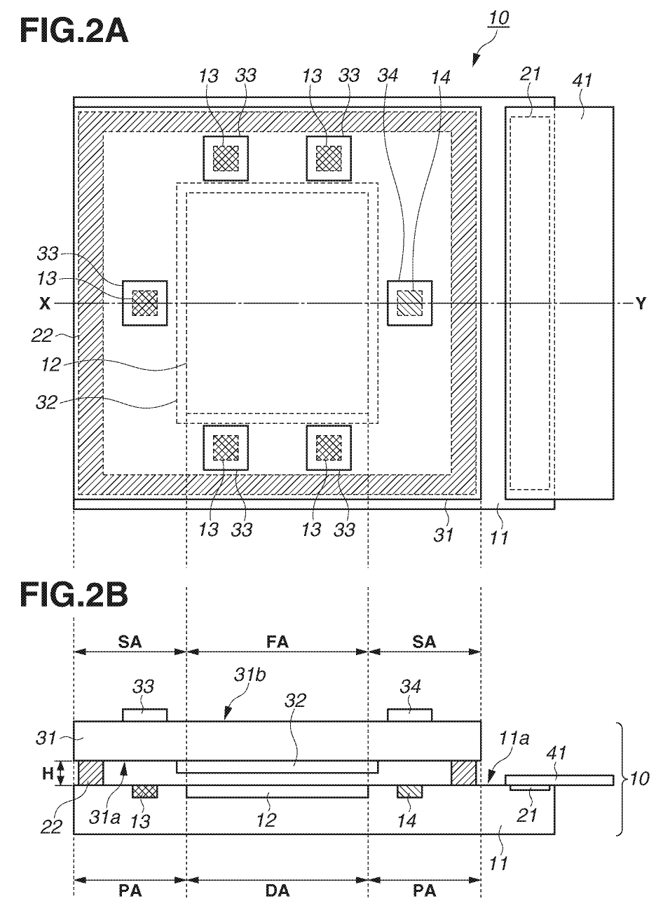

A light-emitting device according to an embodiment of the present disclosure will be described with reference to FIGS. 1 to 4. FIG. 1 is a diagram schematically illustrating a basic configuration of a light-emitting device 10 and a gaze detection operation according to the present embodiment. The light-emitting device 10 includes a display substrate 11 having a surface, i.e. principal surface 11a (illustrated in FIG. 2B and subsequent figures), on which a display element 12, an infrared-emitting element 13, and an infrared-receiving element 14 are disposed. The display element 12 displays an image or the like by emitting display light DL. The infrared-emitting element 13 emits infrared light IR to an eyeball E of an observer gazing at the image or the equivalent thereof displayed on the display element 12. Reflected light of the infrared light IR emitted by the infrared-emitting element 13 is detected by the infrared-receiving element 14, thereby obtaining an image of the eyeball E. The gaze of the observer on the displayed image is detected based on the image of the eyeball E captured using the infrared light IR, with known method(s) of gaze detection used to capture the image of the eyeball E. For example, a gaze detection method based on a Purkinje image formed by the reflection of emitted light on the cornea can be used. A gaze detection process based on the pupil center corneal reflection method is performed. The gaze of the observer is detected by calculating a gaze vector representing the orientation (rotation angle) of the eyeball E based on pupil and Purkinje images included in the captured image of the eyeball E using the pupil center corneal reflection method.

The light-emitting device 10 according to the present embodiment will be described in more detail with reference to FIGS. 2A and 2B. FIG. 2A is a plan view illustrating an example of a configuration of the light-emitting device 10 according to the present embodiment, and FIG. 2B is a cross-sectional view taken along line X-Y in the plan view.

The light-emitting device 10 includes the display substrate 11 and a light-transmitting substrate 31. The principal surface 11a of the display substrate 11 includes a display area DA and a peripheral area PA. The display element 12 is disposed on the display area DA, and the infrared-emitting element 13 and the infrared-receiving element 14 are disposed on the peripheral area PA. The light-transmitting substrate 31 is disposed to cover the principal surface 11a of the display substrate 11. A terminal 21 for external connection or the like is disposed on the principal surface 11a of the display substrate 11. A circuit substrate 41, such as a flexible printed substrate, is joined to the terminal 21 by a joint member. The display substrate 11 and the light-transmitting substrate 31 are joined via a joint member 22 configured to join the display substrate 11 and the light-transmitting substrate 31 so that the principal surface 11a of the display substrate 11 and a principal surface 31a of the light-transmitting substrate 31 face each other. In an orthogonal projection onto the principal surface 11a of the display substrate 11, the infrared-emitting element 13 and the infrared-receiving element 14 are disposed between the display element 12 and the joint member 22, as illustrated in FIG. 2B.

As described above, the display substrate 11 includes the display area DA and the peripheral area PA. The display area DA is provided with the display element 12 and a semiconductor element configured to drive the display element 12, such as a transistor. The peripheral area PA is provided with a drive circuit configured to operate the display element 12 disposed on the display area DA and a processing circuit configured to process a luminance signal input to the display element 12, such as a digital-to-analog converter (DAC). The infrared-emitting element 13, the infrared-receiving element 14, the terminal 21, and the joint member 22 are disposed on the peripheral area PA. A sealing layer may be provided on the display element 12 to protect the display element 12 from external damage, moisture, oxygen, and other factors.

The light-transmitting substrate 31 includes a first area FA and a second area SA. In an orthogonal projection onto the principal surface 11a of the display substrate 11, the first area FA overlaps the display area DA, and the second area SA overlaps the peripheral area PA. In an orthogonal projection onto the principal surface 11a of the display substrate 11, a lens structure 33 is disposed on an overlap area of the second area SA of the light-transmitting substrate 31 that overlaps the infrared-emitting element 13, and a lens structure 34 is disposed on an overlap area of the second area SA that overlaps the infrared-receiving element 14.

For the light-transmitting substrate 31, an inorganic material that transmits light, such as glass or quartz, or a plastic material that transmits light, such as an acrylic resin, is used. In a case where a metalens configuration is formed as the lens structures 33 and 34, quartz can be used as a supporting substrate.

The lens structures 33 and 34 provided to the light-transmitting substrate 31 are formed on a principal surface 31b of the light-transmitting substrate 31. The principal surface 31b is opposite the principal surface 31a facing the display substrate 11. Providing the lens structure 33 above the infrared-emitting element 13 makes it possible to focus infrared light emitted by the infrared-emitting element 13, thereby enhancing extraction efficiency. Providing the lens structure 34 above the infrared-receiving element 14 makes it possible to focus infrared light reflected by the eyeball of the user, thereby enhancing light collecting efficiency at the infrared-receiving element 14. The lens structures 33 and 34 may have the same configuration.

In an orthogonal projection onto the principal surface 11a of the display substrate 11, the lens structure 33 provided to the overlap area that overlaps the infrared-emitting element 13 may be larger than the infrared-emitting element 13, as illustrated in FIGS. 2A and 2B. Similarly, in an orthogonal projection onto the principal surface 11a of the display substrate 11, the lens structure 34 provided to the overlap area that overlaps the infrared-receiving element 14 may be larger than the infrared-receiving element 14. This makes it possible to prevent infrared light incident at an angle to the normal of the principal surface 11a of the display substrate 11 from passing through a portion of the light-transmitting substrate 31 other than the lens structures 33 and 34.

The lens structures 33 and 34 are made of a material that can refract infrared light, such as silicon or gallium arsenide. While the lens structures 33 and 34 are displayed as rectangles in FIGS. 2A and 2B, the lens structures 33 and 34 may be hemispherical. For example, the lens structures 33 and 34 may be formed from a thin amorphous silicon film on the light-transmitting substrate 31, forming a photoresist having a hemispherical lens shape on the amorphous silicon, and transferring the hemispherical lens shape to the amorphous silicon using an etch back technique. Alternatively, the lens structures 33 and 34 may have metalens configurations. A metalens is a nanometer-scale two-dimensional microstructure (metasurface) and can control the phase, amplitude, and polarization of light. A pattern of amorphous silicon structures with a thickness of several hundred nanometers can efficiently refract and focus infrared light. Even in this case, the lens structures 33 and 34 can be formed by forming a thin amorphous silicon film having a thickness of several hundred nanometers on the light-transmitting substrate 31 and then forming a pattern of amorphous silicon structures by photolithography and etching.

In the configurations illustrated in FIGS. 2A and 2B, the display area DA is substantially rectangular. The diagonal length of the display area DA is, for example, 5 mm to 50 mm. According to the present embodiment, as illustrated in FIG. 2A, the infrared-emitting elements 13 are disposed at five areas located along the outside of three sides of the display area DA, and the infrared-receiving element 14 is disposed along the outside of one side of the display area DA where the infrared-emitting elements 13 are not disposed. Even in a case where the infrared-emitting element 13 is disposed at a single area, it is still possible to include the gaze detection function. On the other hand, increasing the number of areas where the infrared-emitting elements 13 are disposed increases the total intensity of infrared light and makes it possible to irradiate the eyeball E of the observer with infrared light from a variety of angles. This makes it possible to prevent the infrared light from being blocked by, for example, the eyelashes of the observer, thereby suppressing degradation of the gaze detection function or the like.

For the joint member 22, for example, an ultraviolet- or heat-curable resin, such as acrylic resin or epoxy resin, is used. The joint member 22 is disposed so as not to cover the infrared-emitting element 13 and the infrared-receiving element 14 in an orthogonal projection onto the principal surface 11a of the display substrate 11. This makes it possible to reduce loss of infrared light transmitted through the joint member 22. In a case where the joint member 22 includes a spacer to maintain a predetermined distance between the display substrate 11 and the light-transmitting substrate 31 or includes an inorganic filler for any other desired purpose, the spacer or the inorganic filler may inhibit transmission of infrared light. Thus, the joint member 22 is disposed so as not to cover the infrared-emitting element 13 and the infrared-receiving element 14.

As illustrated in FIGS. 2A and 2B, an optical film 32, such as a wave plate or polarizing plate, may be disposed on the principal surface 31a of the light-transmitting substrate 31. The optical film 32 may be disposed on the principal surface 31b of the light-transmitting substrate 31. In this case, the optical film 32 may be disposed so as not to cover the lens structures 33 and 34, to reduce loss of infrared light that is caused by the optical film 32.

As described above, according to the present embodiment, the lens structures 33 and 34 are provided on the overlap areas of the light-transmitting substrate 31 that overlap the infrared-emitting element 13 and the infrared-receiving element 14, respectively. This makes it possible to focus infrared light emitted by the infrared-emitting element 13, thereby enhancing extraction efficiency and light collecting efficiency at the infrared-receiving element 14. As a result, the photoreceiving sensitivity to infrared light for gaze detection increases, thereby improving the gaze detection function.

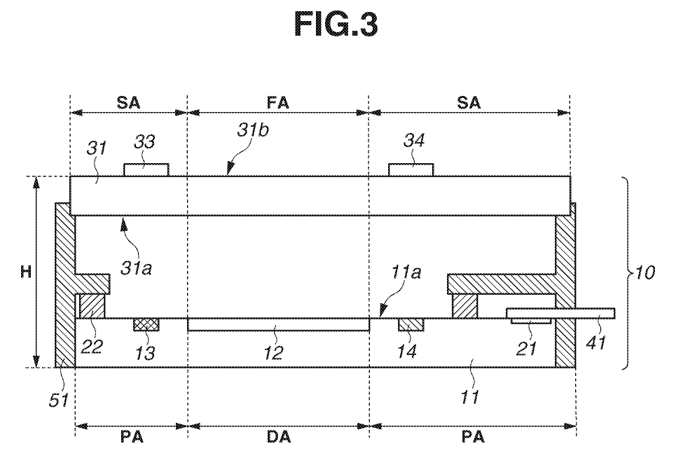

FIG. 3 is a diagram illustrating a modified example of the light-emitting device 10 illustrated in FIGS. 2A and 2B. In the light-emitting device 10 illustrated in FIG. 3, the display substrate 11 is secured to a frame member 51 by the joint member 22, and the light-transmitting substrate 31 is mounted on the frame member 51, compared to the configuration illustrated in FIGS. 2A and 2B. The display substrate 11 and the light-transmitting substrate 31 are disposed so that the principal surface 11a of the display substrate 11 and the principal surface 31a of the light-transmitting substrate 31 face each other, and the frame member 51 defines the distance between the display substrate 11 and the light-transmitting substrate 31. All other components are similar to those illustrated in FIGS. 2A and 2B, with the difference being described herein.

For the frame member 51 in the configuration illustrated in FIG. 3, a material used, may be as a resin, ceramic, or metal, for example, and a resin material that can be easily molded may be used. The frame member 51 may be made of a material that blocks visible light and infrared light because external visible or infrared light passing through the frame member 51 and entering the display substrate 11 may reduce display performance and/or gaze detection performance. For example, the frame member 51 may be made of a liquid crystal polymer containing carbon black. The frame member 51 can be formed using a mold-based resin molding method.

The distance H between the display substrate 11 and the light-transmitting substrate 31 can be set to a desired distance by the frame member 51. Infrared light reflected by the eyeball of the user is focused by the lens structures 33 and 34 provided to the light-transmitting substrate 31 and enters the infrared-receiving element 14, and the infrared light focused by the lens structures 33 and 34 exhibits peak intensity at positions corresponding to the focal lengths. Setting the distance H between the display substrate 11 and the light-transmitting substrate 31 to the focal lengths of the lens structures 33 and 34 makes it possible to enhance the intensity of infrared light entering the infrared-receiving element 14. In a case where the focal lengths of the lens structures 33 and 34 are on the order of several millimeters, the frame member 51 may control the distance H as illustrated in FIG. 3, instead of the distance H being controlled solely by the joint member 22 as illustrated in FIG. 2B, depending on the focal lengths of the lens structures 33 and 34. As described above, providing the frame member 51 makes it possible to set the distance between the display substrate 11 and the light-transmitting substrate 31 based on the focal lengths of the lens structures 33 and 34, thereby making it possible to enhance the intensity of infrared light entering the infrared-receiving element 14. As a result, the photoreceiving sensitivity to infrared light for gaze detection increases, thereby improving the gaze detection function.

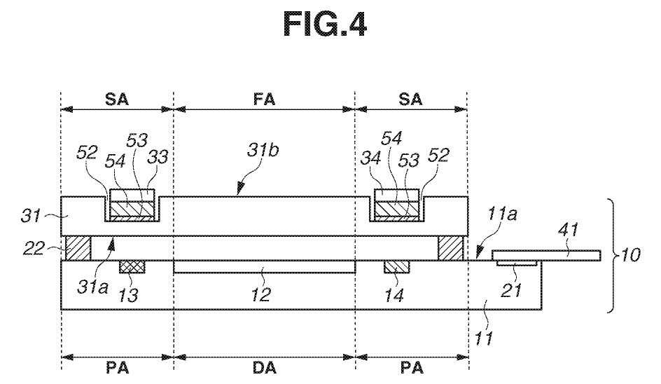

FIG. 4 is a diagram illustrating another modified example of the light-emitting device 10 illustrated in FIGS. 2A and 2B. In the light-emitting device 10 illustrated in FIG. 4, the light-transmitting substrate 31 includes recess portions 52, and supporting substrates 54 on which the lens structures 33 and 34 are provided via adhesives 53 are bonded to bottom portions of the recess portions 52, compared to the configuration illustrated in FIGS. 2A and 2B. All other components are similar to those illustrated in FIGS. 2A and 2B, with the differences being described herein.

For the supporting substrates 54, a material that can transmit light may be used, such as quartz or alkali-free glass, for example. However, in a case where the lens structures 33 and 34 are formed as metalenses, quartz may be used as the supporting substrates 54. The lens structures 33 and 34 are made of amorphous silicon or gallium arsenide and have a hemispherical lens shape or a metalens, as in the embodiments illustrated in FIGS. 2 and 3.

On the surfaces of the supporting substrates 54 opposite the surfaces on which the lens structures 33 and 34 are formed, the adhesives 53 are provided, and the supporting substrates 54 are bonded to the bottom portions of the recess portions 52 of the light-transmitting substrate 31. The supporting substrates 54 are required to be disposed inside the recess portions 52. Thus, considering the mounting position accuracy of the supporting substrates 54, the recess portions 52 are formed to be larger than the supporting substrates 54. Gaps may be formed between side surfaces of the recess portions 52 and the lens structures 33 and 34, thereby allowing the lens structures 33 and 34 to focus infrared light with reduced interference.

In a case where the light-transmitting substrate 31 is made of glass or quartz, it is possible to form the recess portions 52 by etching. In a case where the light-transmitting substrate 31 is made of plastic, the recess portions 52 may be formed by cutting, or the light-transmitting substrate 31 including the recess portions 52 may be formed directly by molding.

For the adhesives 53, an adhesive that can transmit infrared light may be used. While the lens structures 33 and 34 are formed on the light-transmitting substrate 31 in the light-emitting device 10 illustrated in FIGS. 2A and 2B, since the area occupied by the lens structures 33 and 34 is significantly smaller than the total area of the light-transmitting substrate 31, it is less expensive to bond the supporting substrates 54 with the lens structures 33 and 34 to the light-transmitting substrate 31 after forming the lens structures 33 and 34 on the entire surface of a wafer-shaped supporting substrate 54 and then dicing the wafer-shaped supporting substrate 54 with the lens structures 33 and 34. In particular, a significant cost reduction can be achieved by bonding the supporting substrates 54 with metalenses to the light-transmitting substrate 31 made of inexpensive material, such as glass, after forming a metalens on the entire surface of a wafer-shaped quartz supporting substrate and then dicing the wafer-shaped quartz supporting substrate with the metalens, instead of forming a metalens using expensive quartz as the light-transmitting substrate 31. During dicing, a dicing tape with a die attach film may be used, thereby making it possible to use the die attach film as the adhesives 53. This makes it unnecessary to provide a separate adhesive.

By forming the recess portions 52 in the light-transmitting substrate 31 and disposing the supporting substrates 54 inside the recess portions 52, the amount of protrusion of each supporting substrate 54 from the principal surface 31b of the light-transmitting substrate 31 is reduced, which is advantageous for size reduction of the entire module in a case where a lens barrel is provided above the light-transmitting substrate 31. A similar effect is also produced by forming the recess portions 52 in the light-transmitting substrate 31 of the light-emitting device 10 illustrated in FIG. 3 and disposing the supporting substrates 54 with the lens structures 33 and 34 in the recess portions 52. As described above, disposing the supporting substrates 54 with the lens structures 33 and 34 in the recess portions 52 of the light-transmitting substrate 31 makes it possible to achieve cost reduction and module size reduction. Each recess portion 52 can have a depth of 0.1 mm or greater.

Next, a method for manufacturing the light-emitting device 10 will be described. A method for manufacturing the light-emitting device 10 for a case where each pixel disposed on the display element 12 includes a light-emitting element, such as an organic light-emitting element, and the light-emitting device 10 is described as an organic light-emitting device, as an example.

The display substrate 11 may be a semiconductor substrate, such as single-crystal silicon. On the display substrate 11, a semiconductor element is formed. The semiconductor element is, for example, a transistor, a diode, or the like, and at least some of them may be disposed in the display substrate 11. An insulating layer is provided on the semiconductor element. The insulating layer may contain silicon oxide, silicon nitride, silicon carbide, or the like. However, a material used for the insulating layer is not limited to those described above, and any suitable dielectric material may be used. Silicon oxynitride may be considered a type of silicon oxide because oxygen and silicon are major constituent elements. Silicon oxynitride and silicon carbonitride each may be considered a type of silicon nitride because nitrogen and silicon are major constituent elements.

For the insulating layer, a conductive material is used, such as aluminum or copper, and a wiring layer including a wiring pattern extending along the principal surface 11a of the display substrate 11 and the terminal 21 are disposed. The wiring layer including the wiring pattern may be a single layer or a multi-layer including two or more layers. A plug is disposed on the insulating layer to electrically connect the wiring pattern to the semiconductor element and/or the terminal 21. In a case where a plurality of wiring layers including wiring patterns is provided, the plug may electrically connect the wiring patterns of the wiring layers. The terminal 21 may be formed concurrently during wiring pattern formation. In other words, the terminal 21 and at least a portion of the wiring pattern are disposed on the same wiring layer.

The display element 12 is disposed on the display area DA of the display substrate 11. For example, while the display element 12 is illustrated as a whole in FIG. 1, a plurality of pixels each including an organic light-emitting element is disposed, and each pixel emits light at any desired luminance. The display element 12 is electrically connected to the semiconductor element. The organic light-emitting element may include a lower electrode, an organic compound layer including a light-emitting layer, and an upper electrode in this order. The organic light-emitting element may emit light of any desired color including white light. Different pixels may emit light of different colors. A sealing layer is formed on the display element 12 to suppress ingress of moisture, oxygen, or the like, and a color filter layer, a lens structure, or the like may be provided on the sealing layer as necessary.

The infrared-emitting elements 13 are formed on a plurality of areas of the peripheral area PA of the display substrate 11. While the infrared-emitting element 13 is illustrated as a whole in FIG. 1, each infrared-emitting element 13 may be composed of a plurality of light-emitting elements, and each light-emitting element may emit light at any desired luminance. The infrared-emitting element 13 is not particularly limited as long as an infrared-emitting element capable of emitting infrared light is included. For example, the infrared-emitting element 13 may be an organic light-emitting element, a light-emitting diode (LED) element, or the like. In a case where the infrared-emitting element 13 is an organic light-emitting element, the organic light-emitting element disposed on the display element 12 and the infrared-emitting element 13 may be manufactured by the same process, and the number of manufacturing processes may be reduced. In a case where the infrared-emitting element 13 is an organic light-emitting element, the infrared-emitting element 13 may include a lower electrode, an organic compound layer including a light-emitting layer, and an upper electrode in this order, like the display element 12.

The infrared-receiving element 14 is formed on the peripheral area PA of the display substrate 11. While the infrared-receiving element 14 is illustrated as a whole in FIG. 1, each infrared-receiving element 14 may be composed of a plurality of light-receiving elements. The infrared-receiving element 14 may include at least a photoelectric conversion element having infrared-band sensitivity. For the infrared-receiving element 14, for example, a photodiode, an organic photoelectric conversion element, an inorganic photoelectric conversion element, or the like may be used.

For the light-transmitting substrate 31, an inorganic material, such as glass or quartz, or an organic material, such as plastic, e.g., acrylic plate, is used. On the principal surface 31b of the light-transmitting substrate 31, the lens structures 33 and 34 made of amorphous silicon or gallium arsenide are formed by film forming, photolithography, and etching on areas opposite the infrared-emitting element 13 and the infrared-receiving element 14.

The light-transmitting substrate 31 is joined to the display substrate 11 via the joint member 22. For the joint member 22, an ultraviolet-curable acrylic or epoxy resin may be used. On the terminal 21, the circuit substrate 41 is electrically joined via a joint member. The circuit substrate 41 may be a wiring substrate, such as a rigid substrate or a flexible substrate, or a drive circuit chip configured to operate the display element 12. For example, the circuit substrate 41 is a flexible printed circuit board provided with a wiring pattern, such as a glass epoxy substrate or a polyimide film. For the joint member, an anisotropic conductive film (ACF) or the like may be used. The ACF contains conductive particles, and the conductive particles are held between the terminal 21 of the display substrate 11 and an electrode of the circuit substrate 41 and compression-bonded, thereby electrically connecting the terminal 21 of the display substrate 11 and the electrode of the circuit substrate 41. By connecting the display substrate 11 to an external power supply, an external control apparatus, or the like via the circuit substrate 41, the light-emitting device 10 may operate. The foregoing processes are included, and the light-emitting device 10 configured to function as a light-emitting device according to the present embodiment is manufactured.

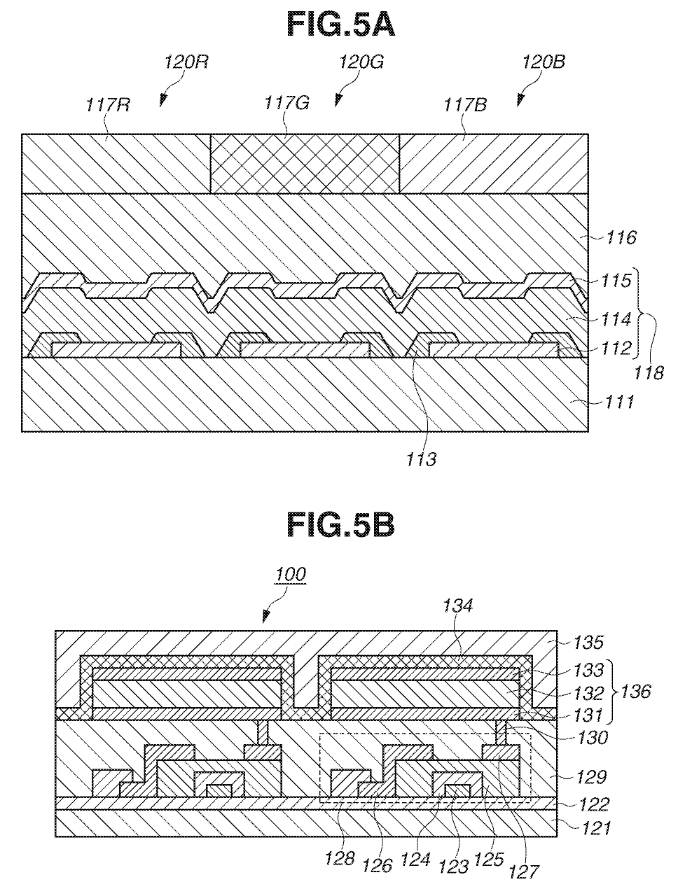

Application examples in which the light-emitting device 10 according to the present embodiment is applied to an image forming apparatus, a display apparatus, a photoelectric conversion apparatus, electronic equipment, a lighting apparatus, a movable object, and a wearable device will be described with reference to FIGS. 5A to 11C. The following description is based on the assumption that, for example, an organic light-emitting element using an organic light-emitting material is disposed on each pixel disposed on the display element 12 of the display substrate 11 of the light-emitting device 10. First, details of each configuration disposed on each pixel disposed on the display element 12 of the display substrate 11 of the light-emitting device 10 will be described, followed by the description of the application examples.

### Configuration of the Organic Light-Emitting Element

The organic light-emitting element is provided by forming an insulating layer, a first electrode, an organic compound layer, and a second electrode on a substrate. A protective layer, a color filter, a microlens, or the like may be provided on a cathode. In a case where the color filter is provided, a planarization layer may be provided between the protective layer and the color filter. The planarization layer may be configured using an acrylic resin or the like. The same applies to a case where a planarization layer is provided between the color filter and the microlens.

### Electrode

A pair of electrodes may be used as an electrode. The pair of electrodes may be an anode and a cathode. In a case where an electric field is applied in the emission direction of the organic light-emitting element, the electrode with a higher electric potential is the anode, and the other is the cathode. It may also be understood that the electrode that supplies holes to the light-emitting layer is the anode and the electrode that supplies electrons is the cathode.

A material having a high work function may be selected as a constituent material of the anode. For example, an elemental metal, such as gold, platinum, silver, copper, nickel, palladium, cobalt, selenium, vanadium, or tungsten, a mixture containing the same, an alloy containing these metals, or a metal oxide, such as tin oxide, zinc oxide, indium oxide, indium tin oxide (ITO), or indium zinc oxide, may be used. A conductive polymer such as polyaniline, polypyrrole, or polythiophene may also be used as a constituent material of the anode.

These electrode substances may be used alone or in combination. The anode may include a single layer or a plurality of layers.

In a case where an electrode is used as a reflective electrode, for example, chromium, aluminum, silver, titanium, tungsten, molybdenum, an alloy thereof, a laminate thereof, or the like may be used. With the foregoing materials, the electrode may function as a reflective film that does not function as an electrode. In a case where a transparent electrode is used as the electrode, materials that can be used include, but are not limited to, oxide transparent conductive layers, such as ITO or indium zinc oxide. Photolithography may be used to form the electrode.

On the other hand, a material having a low work function may be selected as a constituent material of the cathode. Examples include an alkali metal, such as lithium, an alkaline earth metal, such as calcium, an elemental metal, such as aluminum, titanium, manganese, silver, lead, or chromium, and mixtures thereof. An alloy of any combination of these elemental metals may also be used. For example, magnesium-silver, aluminum-lithium, aluminum-magnesium, silver-copper, zinc-silver, or the like may be used. A metal oxide, such as ITO, may also be used. These electrode substances may be used alone or in combination.

The cathode may include a single or a plurality of layers. Silver may be used as the cathode, or a silver alloy may be used to reduce aggregation of silver. Any alloy composition that can reduce silver aggregation may be employed. For example, the ratio of silver to other metals may be 1:1, 3:1, or a similar ratio.

The cathode may be configured as a top emission element using an oxide conductive layer, such as ITO, or as a bottom emission element using a reflective electrode, such as aluminum (Al), and is not particularly limited. While a method for forming the cathode is not particularly limited, good film coverage and reduced resistance of the cathode may be achieved by direct-current or alternating-current sputtering or a similar method.

### Pixel Separation Layer

A pixel separation layer may be formed of silicon nitride (SiN) or silicon oxide, such as silicon oxynitride (SiON) or silicon oxide (SiO), using chemical vapor deposition (CVD). The film thickness of the organic compound layer, in particular a hole-transporting layer, may be reduced at a sidewall of the pixel separation layer to increase the resistance of the organic compound layer in an in-plane direction. A taper angle of the sidewall of the pixel separation layer or the film thickness of the pixel separation layer may be increased, and shadowing may be increased during vapor deposition, thereby reducing the film thickness of the organic compound layer at the sidewall.

On the other hand, the taper angle of the sidewall of the pixel separation layer and the film thickness of the pixel separation layer may be adjusted to the point where no voids form in the protective layer formed thereon. Inhibiting void formation in the protective layer makes it possible to reduce lattice defects in the protective layer. The reduction of lattice defects in the protective layer may inhibit dark spot formation, conduction defects in the second electrode, and other phenomena that lower reliability. These reduction effects are sufficiently achieved in a case where the taper angle of the sidewall of the pixel separation layer is set within the range of 60° to 90°, inclusive. The film thickness of the pixel separation layer may be 10 nm or greater and 150 nm or less. Even in a case where a configuration that only includes a pixel electrode and does not include the pixel separation layer is employed, a similar effect is achieved. In this case, short-circuit formation in the organic light-emitting element may be reduced by adjusting the film thickness of the pixel electrode to one-half the thickness of the organic layer or forming an end portion of the pixel electrode with a forward taper of less than 60°.

In a case where the first electrode is the cathode and the second electrode is the anode, an electron-transporting material and a charge-transport layer may be formed, and a light-emitting layer may be formed on the charge-transport layer, thereby making is possible to achieve high color gamut and low-voltage driving.

### Organic Compound Layer

The organic compound layer may include a single layer or a plurality of layers. In a case where the organic compound layer includes a plurality of layers, the layer may be referred to as a hole-injecting layer, hole-transporting layer, electron-blocking layer, light-emitting layer, hole-blocking layer, electron-transporting layer, or electron-injecting layer, depending on the function of the layer. The organic compound layer primarily includes an organic compound and may further include an inorganic atom or an inorganic compound.

The organic compound layer may include, for example, copper, lithium, magnesium, aluminum, iridium, platinum, molybdenum, zinc, or the like. The organic compound layer may be disposed between the first electrode and the second electrode and may be disposed in contact with the first electrode and the second electrode.

### Protective Layer

A protective layer may be provided on the cathode. For example, glass provided with a desiccant may be bonded to the cathode, thereby reducing ingress of moisture and the like into the organic compound layer and suppressing display defects. As another embodiment, a passivation layer, such as silicon nitride, may be provided on the cathode, thereby reducing ingress of moisture and the like into the organic compound layer. For example, after a cathode is formed, the cathode is conveyed into another chamber without breaking vacuum, and silicon nitride having a thickness of 2 μm is formed by CVD, thereby forming a protective layer. After the protective layer is formed using CVD, another protective layer may be provided using atomic layer deposition (ALD). A material of the protective layer provided using ALD is not limited and may be silicon nitride, silicon oxide, aluminum oxide, or the like. Silicon nitride may be formed using CVD on the protective layer formed using ALD. The protective layer formed using ALD may have a smaller film thickness than that of the protective layer formed using CVD. The film thickness of the protective layer formed using ALD may be 50% or less, or 10% or less, of the film thickness of the protective layer formed using CVD.

### Color Filter

A color filter may be provided on the protective layer. For example, a color filter may be provided on another substrate considering the size of the organic light-emitting element, and the substrate on which the color filter is formed and the substrate provided with the organic light-emitting element may be bonded together. For example, a color filter may be patterned on the protective layer using photolithography. The color filter may include a polymer.

### Planarization Layer

A planarization layer may be disposed between the color filter and the protective layer. The planarization layer is provided to reduce unevenness of the underlying layer. The planarization layer may be referred to as a material resin layer without limiting the purpose. The planarization layer may include an organic compound, which may be a low-molecular-weight compound or a polymer. To reduce unevenness, a polymeric organic compound may be used in the planarization layer.

The planarization layer may be provided above and below the color filter. In this case, the planarization layer above the color filter and the planarization layer below the color filter may include the same or different constituent materials. Polyvinylcarbazole resin, polycarbonate resin, polyester resin, acrylonitrile-butadiene-styrene (ABS) resin, acrylic resin, polyimide resin, phenol resin, epoxy resin, silicone resin, urea resin, or the like may be used as a material of the planarization layer.

### Microlens

The organic light-emitting device may include an optical member, such as a microlens, on its light-emission side.

The microlens may include an acrylic resin, an epoxy resin, or the like. The microlens may be provided to increase the amount of light extracted from the organic light-emitting device and control the direction of the extracted light.

The microlens may have a hemispherical shape. In a case where the microlens has a hemispherical shape, there is a tangent line that is in contact with the hemisphere and parallel to the insulating layer, and the contact point between the tangent line and the hemisphere is the apex of the microlens. The apex of the microlens may be determined similarly in a cross-sectional view. In other words, there is a tangent line that is in contact with a semicircle of the microlens in the cross-sectional view and parallel to the insulating layer, and the contact point between the tangent line and the semicircle is the apex of the microlens.

The midpoint of the microlens may be defined. In the cross-section of the microlens, a virtual line segment from an end point of an arc shape to an end point of another arc shape may be defined, and the midpoint of the line segment may be referred to as the midpoint of the microlens. The cross-section for determining the apex and the midpoint may be a cross-section perpendicular to the insulating layer.

The microlens includes a first surface including a protrusion and a second surface opposite the first surface. The second surface may be disposed on the functional layer (light-emitting layer) side with respect to the first surface. To provide such a configuration, the microlens is formed on the light-emitting device. In a case where the functional layer is an organic layer, a process that reaches a high temperature during a process of manufacturing the microlens may be avoided. In the case of providing a configuration in which the second surface is disposed on the functional layer side with respect to the first surface, the glass transition temperatures of all organic compounds of the organic layer may be 100°C or higher, e.g., 130°C or higher.

### Opposing Substrate

An opposing substrate may be disposed on the planarization layer. The opposing substrate is referred to as the opposing substrate because it is provided at a position corresponding to the substrate. The opposing substrate may include the same constituent material as that of the substrate. In a case where the substrate is defined as a first substrate, the opposing substrate may be defined as a second substrate.

### Organic Compound Layer

The organic compound layer (hole-injecting layer, hole-transporting layer, electron-blocking layer, light-emitting layer, hole-blocking layer, electron-transporting layer, electron-injecting layer, or the like) of the organic light-emitting element according to the embodiment of the present disclosure may be formed by the following method.

For the organic compound layer of the organic light-emitting element according to the embodiment of the present disclosure, a dry process may be used, such as vacuum vapor deposition, ionized vapor deposition, sputtering, or plasma. A wet process in which a material is dissolved in a suitable solvent and a layer is formed using a known coating method (e.g., spin coating, dipping, casting method, Langmuir–Blodgett (LB) method, inkjet method, or the like) may be used instead of a dry process.

A layer formed using a vacuum vapor deposition method, a solution coating method, or the like is less prone to crystallization or the like and has excellent long-term stability. In a case where a coating method is used to form a film, the film may be formed in combination with a suitable binder resin.

Examples of the binder resin include, but are not limited to, polyvinylcarbazole resin, polycarbonate resin, polyester resin, ABS resin, acrylic resin, polyimide resin, phenol resin, epoxy resin, silicone resin, urea resin, and the like.

The binder resins may be used alone as a homopolymer or a copolymer or in combination. A known additive, such as a plasticizer, an oxidation inhibitor, or an ultraviolet absorbent, may be used as appropriate.

### Pixel Circuit

The organic light-emitting device may include a pixel circuit connected to the light-emitting element. The pixel circuit may be an active matrix circuit that individually controls light emission of a first light-emitting element and a second light-emitting element. The active matrix circuit may be configured to perform voltage programming or current programming. A drive circuit includes a pixel circuit for each pixel. The pixel circuit may include a light-emitting element, a transistor configured to control the emission luminance of the light-emitting element, a transistor configured to control the emission timing, a capacitor configured to hold a gate voltage of the transistor configured to control the emission luminance, and a transistor configured to connect to ground without passing through the light-emitting element.

The pixel circuit is disposed on the display area DA, and the peripheral area PA includes a display control circuit. The mobilities of the transistors of the pixel circuit may be lower than the mobility of a transistor of the display control circuit.

The gradients of the current–voltage characteristics of the transistors of the pixel circuit may be less than the gradient of the current–voltage characteristic of the transistor of the display control circuit. The gradients of the current–voltage characteristics can be measured from a Vg-Ig characteristic.

The transistors of the pixel circuit are transistors connected to a light-emitting element, such as the first light-emitting element.

### Pixel

The organic light-emitting device includes a plurality of pixels. Each pixel includes sub-pixels configured to emit light of different colors. For example, the emission colors of the sub-pixels may be red, green, and blue (RGB).

Each pixel has a region that emits light, which is also referred to as a pixel aperture. The pixel aperture may be 15 μm or less and 5 μm or greater. The pixel aperture may be 11 μm, 9.5 μm, 7.4 μm, 6.4 μm, or the like.

The distance between the sub-pixels may be 10 μm or less. Specifically, the distance may be 8 μm, 7.4 μm, or 6.4 μm.

The pixels may be arranged in a known pattern in plan view. Examples include stripe, delta, pentile, and Bayer arrangements. The sub-pixels may have any known shape in plan view. Examples include quadrilateral shapes, such as rectangles and rhombuses, and hexagonal shapes. It is apparent that a shape that is approximately, but not exactly, is included among the rectangles. The sub-pixel shape and a pixel array may be used in combination.

### Application of the Light-Emitting Device

The light-emitting device according to the embodiment of the present disclosure may be used as a component of a display apparatus or a lighting apparatus. The light-emitting device may be used as an exposure light source of an electrophotographic image forming apparatus, a backlight of a liquid crystal display apparatus, a light-emitting device including a white light source and a color filter, or the like.

The display apparatus may be an image information processing apparatus that includes an image input unit configured to input image information from an area charge-coupled device (area CCD), a linear charge-coupled device (linear CCD), a memory card, or the like and an information processing unit configured to process the input information and displays the input image on a display unit.

A display unit of an imaging apparatus or an inkjet printer may include a touch panel function. A method for driving the touch panel function is not particularly limited, and an infrared, capacitive, resistive, or electromagnetic induction type may be employed. The display apparatus may be used in a display unit of a multi-function printer.

FIG. 5A illustrates an example of a pixel of the display element 12 of the display substrate 11 of the light-emitting device 10. The pixel includes sub-pixels (pixel). The sub-pixels 120 are separated into sub-pixels 120R, 120G, and 120B (collectively 120) according to their light emission. Emission colors may be distinguished by emission wavelengths of the light-emitting layer, or a color filter or the like may selectively transmit light emitted from each sub-pixel 120 or perform color conversion on the light. Each sub-pixel 120 includes a reflective electrode 112, which is a first electrode, on an interlayer insulating layer 111, an insulating layer 113 covering edges of the reflective electrode 112, an organic compound layer 114 covering the reflective electrode 112 and the insulating layer 113, a transparent electrode 115, which is a second electrode, a protective layer 116, and a color filter 117R, 117G, 117B (collectively 117). The reflective electrode 112, the organic compound layer 114, and the transparent electrode 115 constitute an organic light-emitting element 118.

A transistor and a capacitor element may be disposed on a layer underlying the interlayer insulating layer 111 or inside the interlayer insulating layer 111. The transistor and the first electrode may be electrically connected via a contact hole or the like.

The insulating layer 113 may also be referred to as a bank or a pixel separation film. The insulating layer 113 covers the edges of the reflective electrode 112 and is disposed to surround the reflective electrode 112. A portion of the reflective electrode 112 where the insulating layer 113 is not disposed is in contact with the organic compound layer 114 and serves as a light emission area. The second electrode may be a transparent electrode, a reflective electrode, or a semi-transparent electrode.

The protective layer 116 reduces ingress of moisture into the organic compound layer. While the protective layer 116 illustrated as a single layer in FIG. 5A, the protective layer 116 may include a plurality of layers, and an inorganic compound layer and an organic compound layer may be provided for each layer.

The color filter 117 is separated into color filters 117R, 117G, and 117B according to their colors.

The color filter 117 may be formed on a planarization film. A resin protective layer may be disposed on the color filter 117. The color filter 117 may be formed on the protective layer 116. The color filter 117 may be provided on an opposing substrate, such as a glass substrate, and then bonded.

FIG. 5B illustrates a display apparatus 100 (corresponding to the light-emitting device 10) including an organic light-emitting element 136 and a thin-film transistor (TFT) 128 as an example of a transistor. A substrate 121, such as glass or silicon, is provided, and an insulating layer 122 is provided on the substrate 121. An active element, such as the TFT 128, is disposed on the insulating layer 122, and a gate electrode 123 of the active element, a gate insulating film 124, and a semiconductor layer 125 are arranged. The TFT 128 further includes the semiconductor layer 125, a drain electrode 126, and a source electrode 127. An insulating film 129 is provided on the TFT 128. An anode 131 of the organic light-emitting element 136 and the source electrode 127 are connected via a contact hole 130 of the insulating film 129.

A method for electrically connecting an electrode (anode, cathode) of the organic light-emitting element 136 and an electrode (source electrode, drain electrode) of the TFT 128 is not limited to that illustrated in FIG. 5B. Either the anode or the cathode may be electrically connected to either the source electrode or the drain electrode of the TFT 128.

While an organic compound layer 132 is illustrated as a single layer in the display apparatus 100 in FIG. 5B, the organic compound layer 132 may include a plurality of layers. A first protective layer 134 and a second protective layer 135 are provided on a cathode 133 to reduce degradation of the organic light-emitting element 136.

While a transistor is used as a switching element in the display apparatus 100 in FIG. 5B, another switching element may be used in place of the transistor.

The transistors used in the display apparatus 100 in FIG. 5B are not limited to transistors that use single-crystal silicon wafers, and a thin-film transistor that includes an active layer on an insulating surface of the substrate 121. The active layer may be, for example, single-crystal silicon, amorphous silicon, non-monocrystalline silicon, such as microcrystalline silicon, or non-monocrystalline oxide semiconductor, such as indium zinc oxide or indium gallium zinc oxide. The thin-film transistor is also referred to as a TFT element.

The transistors included in the display apparatus 100 in FIG. 5B may be formed within the substrate 121, such as a silicon substrate. Being formed within the substrate 121 herein indicates that the transistor is fabricated by processing the substrate 121, such as a silicon substrate. In other words, the substrate 121 including a transistor may be regarded as the transistor being integrally formed with the substrate 121.

The emission luminance of the organic light-emitting element 136 according to the present embodiment is controlled by the TFT 128, which is an example of a switching element, and the plurality of organic light-emitting elements 136 is provided inside, thereby displaying an image based on the emission luminance of each organic light-emitting element 136. The switching element according to the present embodiment is not limited to a TFT and may be a transistor formed of low-temperature polysilicon or an active matrix driver formed on the substrate 121, such as a silicon substrate. As described herein, provided on the substrate 121 may also be regarded as being included in the substrate 121. It is determined whether to provide a transistor in the substrate 121 or use the TFT 128 based on the size of the display unit. For example, in a case where the size is approximately 0.5 inches, the organic light-emitting elements 136 may be provided on the silicon substrate.

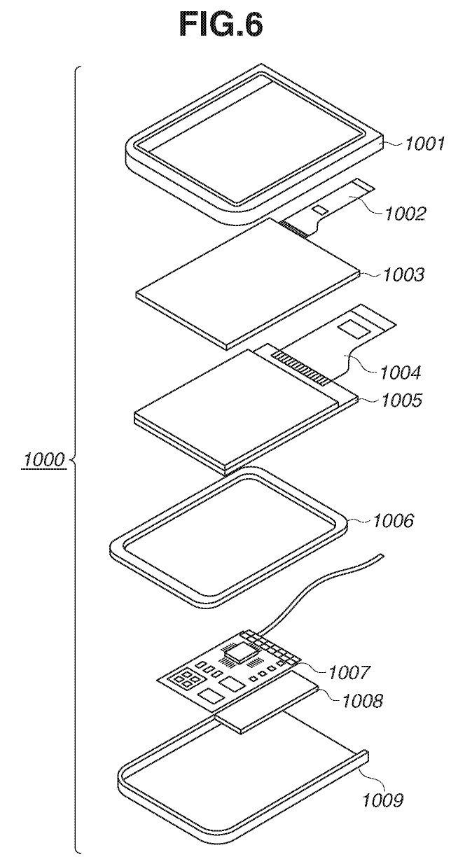

FIG. 6 is a schematic diagram illustrating an example of a display apparatus using the light-emitting device 10 according to the present embodiment. A display apparatus 1000 may include a touch panel 1003, a display panel 1005, a frame 1006, a circuit substrate 1007, and a battery 1008 between an upper cover 1001 and a lower cover 1009. Flexible printed circuits FPC 1002 and 1004 are connected to the touch panel 1003 and the display panel 1005. An active element, such as a transistor, is disposed on the circuit substrate 1007. The battery 1008 is optional in a case where the display apparatus 1000 is not a mobile phone. Even in a case where the display apparatus 1000 is a mobile phone, the battery 1008 does not have to be provided at the illustrated position. The light-emitting device 10 is applicable to the display panel 1005. A pixel disposed on the light-emitting device 10 configured to function as the display panel 1005 is connected to an active element disposed on the circuit substrate 1007, such as a transistor, and operates.

The display apparatus 1000 illustrated in FIG. 6 may be used as a display unit of a photoelectric conversion apparatus (also referred to as an imaging apparatus) that includes an optical unit including a plurality of lenses and an image sensor configured to receive light transmitted through the optical unit and photoelectrically convert the received light into an electrical signal. The photoelectric conversion apparatus may include a display unit configured to display information acquired by the image sensor. The display unit may be exposed from the photoelectric conversion apparatus or arranged within a finder. The photoelectric conversion apparatus may be a digital camera or a digital video camera.

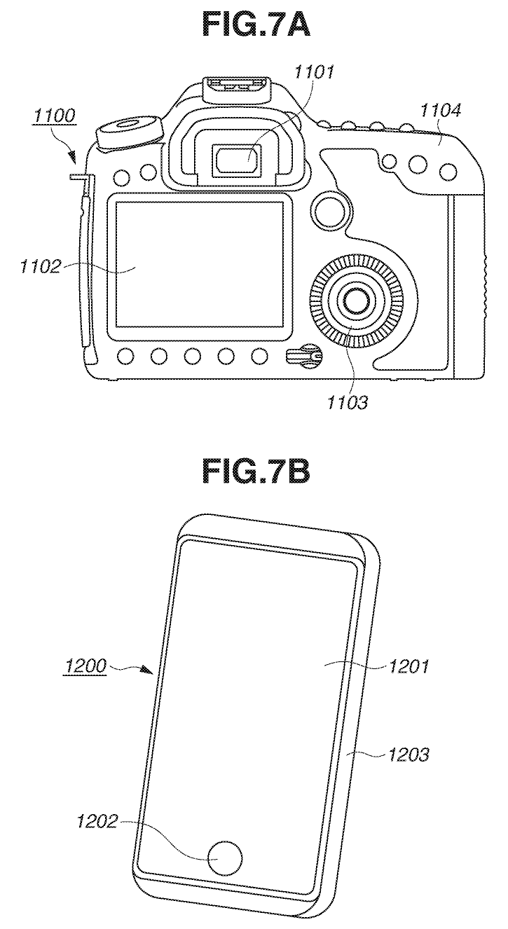

FIG. 7A is a schematic diagram illustrating an example of a photoelectric conversion apparatus using the light-emitting device 10 according to the present embodiment. A photoelectric conversion apparatus 1100 may include a viewfinder 1101, a rear display 1102, an operation unit 1103, and a housing 1104. The photoelectric conversion apparatus 1100 may also be referred to as an imaging apparatus. The light-emitting device 10 according to the present embodiment is applicable to the viewfinder 1101 and the rear display 1102, which are a display unit. In this case, the light-emitting device 10 may display not only a captured image but also environment information, an imaging instruction, and the like. The environment information may include the intensity of external light, the orientation of external light, the velocity of a moving subject, the possibility that the subject may be occluded by an obstruction, and the like.

The timing suitable for capturing an image is often very brief. Thus, information should be displayed as soon as possible. Thus, the light-emitting device 10 on which a pixel including an organic light-emitting element using an organic light-emitting material is disposed may be used in the viewfinder 1101 and the rear display 1102. This is due to a short response time. The light-emitting device 10 using an organic light-emitting material is more suitable for the apparatuses that are required to have a short display time than the liquid crystal display apparatus.

The photoelectric conversion apparatus 1100 includes an optical unit. The optical unit includes a plurality of lenses and forms an image on a photoelectric conversion element configured to receive light transmitted through the optical unit and included in the housing 1104. The focal point is adjustable by adjusting the relative positions of the plurality of lenses. It is also possible to perform this operation automatically.

The light-emitting device 10 may be applied to a display unit of electronic equipment. In this case, the light-emitting device 10 may include both a display function and an operation function. Examples of mobile terminals include a mobile phone, such as a smartphone, a tablet, a head-mounted display, and the like.

FIG. 7B is a schematic diagram illustrating an example of electronic equipment using the light-emitting device 10 according to the present embodiment. Electronic equipment 1200 includes a display unit 1201, an operation unit 1202, and a housing 1203.

The housing 1203 may include a circuit, a printed substrate including the circuit, a battery, and a communication unit. The operation unit 1202 may be a button or a sensing unit of a touch panel. The operation unit 1202 may be a biometric recognition unit configured to recognize a fingerprint, unlock the electronic equipment 1200, and the like. A mobile device including the communication unit may also be regarded as a communication device. The light-emitting device 10 according to the present embodiment is applicable to the display unit 1201.

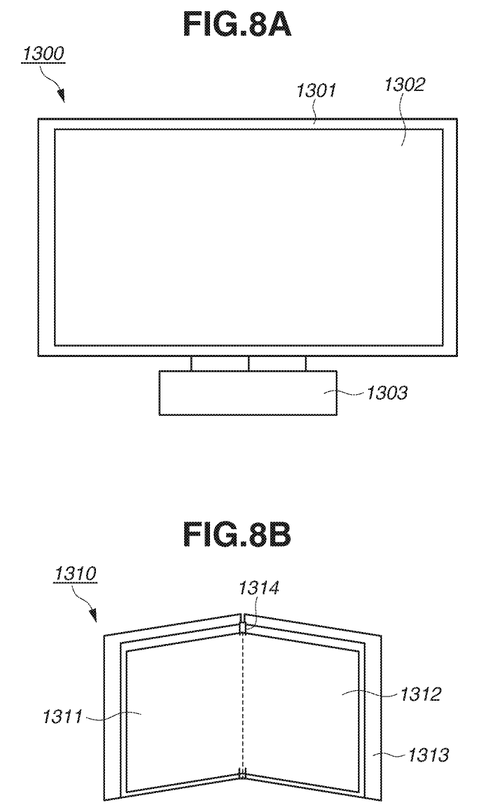

FIGS. 8A and 8B are schematic diagrams illustrating examples of a display apparatus using the light-emitting device 10 according to the present embodiment. FIG. 8A illustrates a display apparatus such as a television monitor or a personal computer (PC) monitor. A display apparatus 1300 includes a frame 1301 and a display unit 1302. The light-emitting device 10 according to the present embodiment is applicable to the display unit 1302. The display apparatus 1300 may include a base 1303 supporting the frame 1301 and the display unit 1302. The base 1303 is not limited to that illustrated in FIG. 8A. For example, the lower side of the frame 1301 may also function as the base 1303. The frame 1301 and the display unit 1302 may be curved. The radius of curvature may be 5000 mm or greater and 6000 mm or less.

FIG. 8B is a schematic diagram illustrating another example of a display apparatus using the light-emitting device 10 according to the present embodiment. A display apparatus 1310 illustrated in FIG. 8B is a foldable display apparatus configured to folded. The display apparatus 1310 includes a first display unit 1311, a second display unit 1312, a housing 1313, and a folding line 1314. The light-emitting device 10 according to the present embodiment is applicable to the first display unit 1311 and the second display unit 1312. The first display unit 1311 and the second display unit 1312 may be a single seamless display apparatus. The first display unit 1311 and the second display unit 1312 may be divided at the folding line 1314. The first display unit 1311 and the second display unit 1312 may display different images, or the first display unit 1311 and the second display unit 1312 may collectively display a single image.

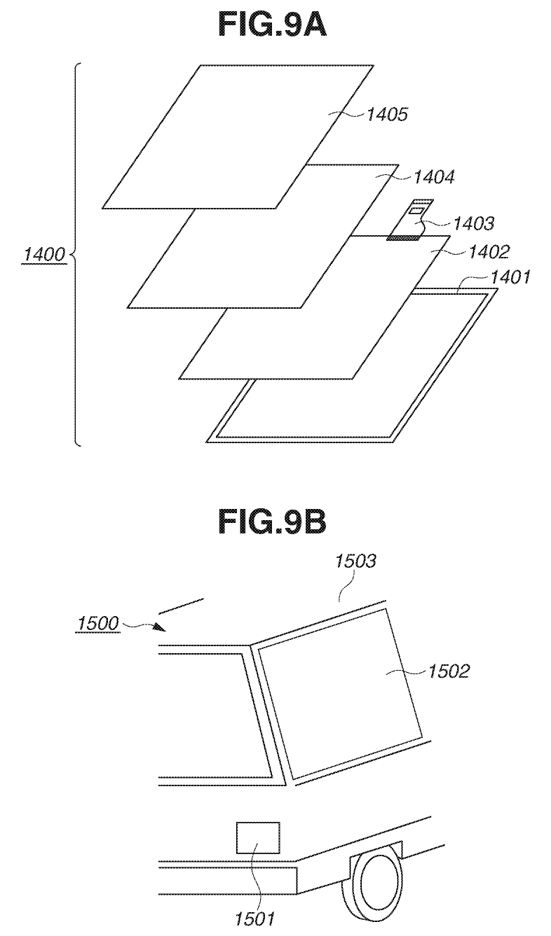

FIG. 9A is a schematic diagram illustrating an example of a lighting apparatus using the light-emitting device 10 according to the present embodiment. A lighting apparatus 1400 includes a housing 1401, a light source 1402, a circuit substrate 1403, an optical film 1404, and a light-diffusing portion 1405. The light-emitting device 10 according to the present embodiment is applicable to the light source 1402. The optical film 1404 may be a filter that improves the color rendering of the light source 1402. The light-diffusing portion 1405 effectively diffuses light from the light source 1402 for illumination or other purposes, thereby delivering light over a wide area. A cover may be provided to the outermost portion as appropriate. The lighting apparatus 1400 may include either or both of the optical film 1404 and the light-diffusing portion 1405.

The lighting apparatus 1400 is, for example, an apparatus for illuminating an indoor space. The lighting apparatus 1400 may emit white, daylight white, or a color in the range from blue to red. A light modulating circuit configured to modulate the light may be included. The lighting apparatus 1400 may include a power supply circuit connected to the light-emitting device 10 configured to function as the light source 1402. The power supply circuit converts alternating-current voltage into direct-current voltage. With reference to a color temperature of 4200 K, daylight white refers to a color temperature of 5000 K. The lighting apparatus 1400 may include a color filter. The lighting apparatus 1400 may include a heat dissipation portion. The heat dissipation portion removes heat from the inside the lighting apparatus 1400 to the outside, and examples include a metal with high specific heat, liquid silicon, and the like.

FIG. 9B is a schematic diagram illustrating an automobile including a tail lamp that is an example of a vehicle lighting apparatus using the light-emitting device 10 according to the present embodiment. An automobile 1500 may include a tail lamp 1501 and turn on the tail lamp 1501 when an braking operation is performed.

The light-emitting device 10 according to the present embodiment may be used as a vehicle lighting apparatus in a headlamp. The automobile 1500 is an example of a movable object, and the movable object may be a ship, a drone, an aircraft, a railway vehicle, an industrial robot, or the like. The movable object may include a body and a lighting apparatus provided to the body. The lighting apparatus may be configured to provide notification of the current position of the body.

The light-emitting device 10 according to the present embodiment is applicable to the tail lamp 1501. The tail lamp 1501 may include a protective member configured to protect the light-emitting device 10 configured to function as the tail lamp 1501. For the protective member, any material that has relatively high strength and is transparent may be used, and the protective member may include polycarbonate or the like. The protective member may include a mixture of polycarbonate and a furandicarboxylic acid derivative, an acrylonitrile derivative, or the like.

The automobile 1500 may include a body 1503 and a window 1502 attached to the body 1503. The window 1502 may be a window for checking the front and rear of the automobile 1500 or a transparent display, such as a head-up display. The light-emitting device 10 according to the present embodiment may be used in the transparent display. In this case, the electrodes and other constituent materials of the light-emitting device 10 are formed from transparent materials.

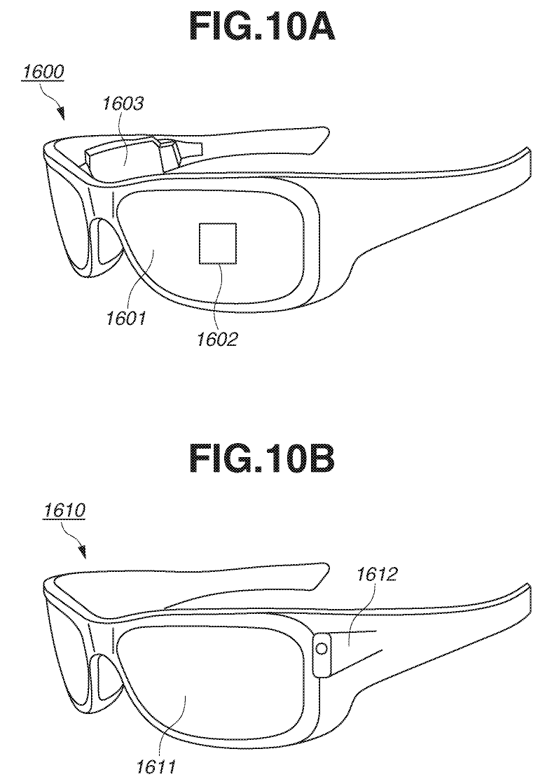

Further applications of the light-emitting device 10 according to the present embodiment will be described with reference to FIGS. 10A and 10B. The light-emitting device 10 is applicable to a system wearable as a wearable device, such as smart glasses, a head-mounted display (HMD), or smart contact lenses.

An imaging display apparatus used in such application examples include an imaging apparatus configured to photoelectrically convert visible light and a light-emitting device configured to emit visible light.

FIG. 10A illustrates glasses 1600 (smart glasses) according to an application example. An imaging apparatus 1602, such as a complementary metal-oxide-semiconductor (CMOS) sensor or a single-photon avalanche diode (SPAD), is provided to the front side of a lens 1601 of the glasses 1600. The light-emitting device 10 according to the present embodiment is provided to the rear side of the lens 1601.

The glasses 1600 further include a control apparatus 1603. The control apparatus 1603 functions as a power supply to supply power to an imaging apparatus 1602 and the light-emitting device 10 according to the embodiment. The control apparatus 1603 controls the operation of the imaging apparatus 1602 and the light-emitting device 10. An optical system is formed on the lens 1601 to focus light onto the imaging apparatus 1602.

FIG. 10B illustrates glasses 1610 (smart glasses) according to another application example. The glasses 1610 includes a control apparatus 1612, and the control apparatus 1612 is equipped with an imaging apparatus corresponding to the imaging apparatus 1602 and the light-emitting device 10. The imaging apparatus in the control apparatus 1612 and an optical system configured to project light emitted by the light-emitting device 10 are formed on a lens 1611, and an image is projected onto the lens 1611. The control apparatus 1612 functions as a power supply to supply power to the imaging apparatus and the light-emitting device 10 and controls the operation of the imaging apparatus and the light-emitting device 10. The control apparatus 1612 may include a gaze detection unit configured to detect the gaze of the wearer. Infrared light may be used to detect the gaze. An infrared-emitting unit emits infrared light to an eyeball of a user gazing at a displayed image. The emitted infrared light reflected by the eyeball is detected by an imaging unit including a light-receiving element, thereby capturing an image of the eyeball. A reduction unit may be included to reduce light from the infrared-emitting unit to a display unit in plan view, thereby reducing degradation of image quality.

The gaze of the user at the displayed image is detected from the image of the eyeball captured using infrared light. Any known method is applicable to gaze detection using the captured image of the eyeball. For example, a gaze detection method based on a Purkinje image caused by reflection of emitted light on the cornea may be used.

A gaze detection process based on the pupil center corneal reflection method is performed. Using the pupil center corneal reflection method, a gaze vector representing the orientation (rotation angle) of the eyeball is calculated based on the pupil and Purkinje images included in the captured image of the eyeball, thereby detecting the gaze of the user.

The light-emitting device 10 according to the embodiment of the present disclosure may include an imaging apparatus including a light-receiving element and control a displayed image based on user gaze information from the imaging apparatus.

The light-emitting device 10 determines a first field-of-view region at which the user gazes and a second field-of-view region other than the first field-of-view region based on the gaze information. The first field-of-view region and the second field-of-view region may be determined by a control apparatus of the light-emitting device 10, or the first field-of-view region and the second field-of-view region determined by an external control apparatus may be received. In a display area of the light-emitting device 10, the display resolution of the first field-of-view region may be controlled to be higher than the display resolution of the second field-of-view region. In other words, the resolution of the second field-of-view region may be set lower than the resolution of the first field-of-view region.

The display area may include a first display area and a second display area different from the first display area, and a high-priority region is determined from the first display area and the second display area based on the gaze information.

The first display area and the second display area may be determined by the control apparatus of the light-emitting device 10, or the first display area and the second display area determined by an external control apparatus may be received. The resolution of the high-priority region may be controlled to be higher than the resolution of a region other than the high-priority region. In other words, a region having relatively low priority may be set with low resolution.

Artificial intelligence (AI) may be used to determine the first field-of-view region and/or the high-priority region. AI may be a model configured to estimate the angle of the gaze and the distance to a target object beyond the gaze based on the image of the eyeball using the image of the eyeball and the direction of the actual gaze of the eyeball of the image as training data. An AI program may be included in the light-emitting device 10, the imaging apparatus, or an external apparatus. In a case where an external apparatus includes the AI program, the AI program is transmitted to the light-emitting device 10 via communication.

In the case of performing display control based on visual recognition detection, application to smart glasses further including an imaging apparatus configured to capture an image of the outside is possible. The smart glasses are capable of displaying captured external information in real time.

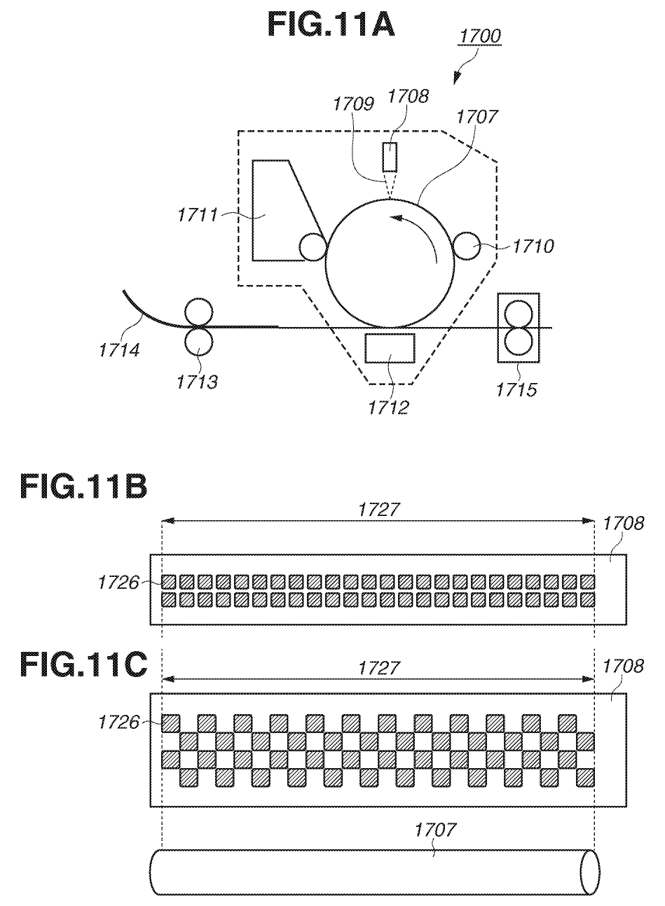

FIGS. 11A to 11C are schematic diagrams illustrating an example of an image forming apparatus using the light-emitting device 10 according to the present embodiment. An image forming apparatus 1700 illustrated in FIG. 11A includes a photoconductor 1707, an exposure light source 1708, a developing portion 1711, a charging portion 1710, a transfer device 1712, a conveyance portion 1713 (conveyance roller), and a fixing device 1715.

The exposure light source 1708 emits light 1709, thereby forming an electrostatic latent image on a surface of the photoconductor 1707. The light-emitting device 10 is applicable to the exposure light source 1708. The developing portion 1711 may include toner or the like as a developer and function as a developing device configured to apply the developer to the exposed photoconductor 1707. The charging portion 1710 charges the photoconductor 1707. The transfer device 1712 transfers a developed image onto a recording medium 1714. The conveyance portion 1713 conveys the recording medium 1714. The recording medium 1714 may be, for example, paper, a film, or the like. The fixing device 1715 fixes the image formed on the recording medium 1714.

FIGS. 11B and 11C are schematic diagrams illustrating a plurality of light-emitting portions 1726 of the exposure light source 1708 arranged on an elongated substrate along a longitudinal direction. The light-emitting device 10 may be applied to the light-emitting portions 1726. In other words, a plurality of pixels is arranged along the longitudinal direction of the substrate. A direction 1727 is parallel to a shaft of the photoconductor 1707. This column direction corresponds to the direction of the shaft during rotation of the photoconductor 1707. The direction 1727 may also be referred to as a major-axis direction of the photoconductor 1707.

FIG. 11B illustrates the light-emitting portions 1726 arranged along the major-axis direction of the photoconductor 1707. FIG. 11C illustrates a modified example of the arrangement of the light-emitting portions 1726 illustrated in FIG. 11B, and the light-emitting portions 1726 are alternately arranged in first and second columns along the column direction. In the first and second columns, the light-emitting portions 1726 are arranged at different positions in the row direction. In the first column, the light-emitting portions 1726 are arranged with intervals therebetween, and in the second column, the light-emitting portions 1726 are arranged at positions corresponding to the intervals between the light-emitting portions 1726 in the first column. Similarly, in the row direction, the light-emitting portions 1726 are arranged with intervals therebetween. The arrangement of the light-emitting portions 1726 illustrated in FIG. 11C may also be referred to as, for example, a state where the light-emitting portions 1726 are arranged in a lattice pattern, a state where the light-emitting portions 1726 are arranged in a houndstooth pattern, or a checked pattern.

### Example Configurations

Examples of the present disclosure include a light-emitting device, a photoelectric conversion apparatus, and electronic equipment, as described below.

### Configuration 1

A light-emitting device including a display substrate having a principal surface including a display area on which a display element is disposed and a peripheral region on which an infrared-emitting element and an infrared-receiving element are disposed and a light-transmitting substrate facing the principal surface, wherein the light-transmitting substrate includes a first area overlapping the display area and a second area overlapping the peripheral region in an orthogonal projection onto the principal surface, and wherein a lens structure is provided on each of an overlap area of the second area of the light-transmitting substrate that overlaps the infrared-emitting element and an overlap area of the second area of the light-transmitting substrate that overlaps the infrared-receiving element.

### Configuration 2

The light-emitting device according to configuration 1, wherein the light-transmitting substrate and the display substrate are bonded via a joint member.

### Configuration 3

The light-emitting device according to configuration 1 or 2, wherein the lens structure is made of amorphous silicon or gallium arsenide and has a hemispherical lens shape or a metalens configuration.

### Configuration 4

The light-emitting device according to any one of configurations 1 to 3, wherein an optical film is disposed on at least one of two principal surfaces of the light-transmitting substrate, and the optical film does not cover the lens structure.

### Configuration 5

The light-emitting device according to any one of configurations 1 to 4, wherein in the orthogonal projection onto the principal surface, the lens structure provided to the overlap area of the second area that overlaps the infrared-emitting element is larger than the infrared-emitting element, and the lens structure provided to the overlap area of the second area that overlaps the infrared-receiving element is larger than the infrared-receiving element.

### Configuration 6

The light-emitting device according to any one of configurations 1 to 5, wherein a frame member is provided between the light-transmitting substrate and the display substrate, and the display substrate and the frame member are bonded by a joint member.

### Configuration 7

The light-emitting device according to configuration 6, wherein the frame member contains a material configured to absorb at least one of visible light and infrared light.

### Configuration 8

The light-emitting device according to any one of configurations 1 to 7, wherein the lens structure is provided on a supporting substrate configured to transmit light, and the supporting substrate is bonded in the overlap region of the second area that overlaps the infrared-emitting element and is bonded in the overlap region of the second area that overlaps the infrared-receiving element.

### Configuration 9

The light-emitting device according to configuration 8, wherein the light-transmitting substrate includes a recess portion opposite the display substrate, and the supporting substrate is bonded to a bottom portion of the recess portion.

### Configuration 10

The light-emitting device according to configuration 9, wherein the recess portion has a depth of 0.1 mm or greater.

### Configuration 11

The light-emitting device according to configuration 9 or 10, wherein a gap is between the lens structure and a side surface of the recess portion.

### Configuration 12

The light-emitting device according to any one of configurations 8 to 11, wherein the supporting substrate and the lens structure are bonded with a die attach film.

### Configuration 13

A display apparatus including the light-emitting device according to any one of configurations 1 to 12 and an active element connected to the light-emitting device.

### Configuration 14

A photoelectric conversion apparatus including an optical unit including a plurality of lenses, an image sensor configured to receive light transmitted through the optical unit, and a display unit configured to display an image, wherein the display unit displays an image captured by the image sensor and includes the light-emitting device according to any one of configurations 1 to 12.

### Configuration 15

Electronic equipment including a housing provided with a display unit and a communication unit provided to the housing and configured to perform external communication, wherein the display unit includes the light-emitting device according to any one of configurations 1 to 12.

### Configuration 16

A wearable device including a display apparatus configured to display an image, wherein the display apparatus includes the light-emitting device according to any one of configurations 1 to 12.

The present disclosure is not limited to the above-described embodiments, and various changes and modifications can be made without departing from the spirit and scope of thereof.

The present disclosure provides a light-emitting device that suppresses a decrease in photo-receiving sensitivity to infrared light.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-034432, filed Mar. 5, 2025, which is hereby incorporated by reference herein in its entirety.

What is claimed is:

1. A light-emitting device comprising:
a display substrate having a surface including a display area on which a display element is disposed and a peripheral region on which an infrared-emitting element and an infrared-receiving element are disposed; and
a light-transmitting substrate facing the surface,
wherein the light-transmitting substrate includes a first area overlapping the display area and a second area overlapping the peripheral region in an orthogonal projection onto the surface, and
wherein a lens structure is provided on each of an overlap area of the second area of the light-transmitting substrate that overlaps the infrared-emitting element and an overlap area of the second area of the light-transmitting substrate that overlaps the infrared-receiving element.

2. The light-emitting device according to claim 1, wherein the light-transmitting substrate and the display substrate are bonded via a joint member.

3. The light-emitting device according to claim 1, wherein the lens structure is made of either amorphous silicon or gallium arsenide and has a hemispherical lens shape or a metalens configuration.

4. The light-emitting device according to claim 1, wherein an optical film is disposed on at least one of two surfaces of the light-transmitting substrate, and the optical film does not cover the lens structure.

5. The light-emitting device according to claim 1, wherein in the orthogonal projection onto the surface, the lens structure provided to the overlap area of the second area that overlaps the infrared-emitting element is larger than the infrared-emitting element, and the lens structure provided to the overlap area of the second area that overlaps the infrared-receiving element is larger than the infrared-receiving element.

6. The light-emitting device according to claim 1, wherein a frame member is provided between the light-transmitting substrate and the display substrate, and the display substrate and the frame member are bonded by a joint member.

7. The light-emitting device according to claim 6, wherein the frame member contains a material configured to absorb at least one of visible light or infrared light.

8. The light-emitting device according to claim 1, wherein the lens structure is provided on a supporting substrate configured to transmit light, and the supporting substrate is bonded in the overlap region of the second area that overlaps the infrared-emitting element and is bonded in the overlap region of the second area that overlaps the infrared-receiving element.

9. The light-emitting device according to claim 8, wherein the light-transmitting substrate includes a recess portion opposite the display substrate, and the supporting substrate is bonded to a bottom portion of the recess portion.

10. The light-emitting device according to claim 9, wherein the recess portion has a depth of 0.1 mm or greater.

11. The light-emitting device according to claim 9, further comprising a gap between the lens structure and a side surface of the recess portion.

12. The light-emitting device according to claim 8, wherein the supporting substrate and the lens structure are bonded with a die attach film.

13. A display apparatus comprising:
the light-emitting device according to claim 1; and
an active element connected to the light-emitting device.

14. A photoelectric conversion apparatus comprising:
an optical unit including a plurality of lenses;
an image sensor configured to receive light transmitted through the optical unit; and
a display unit configured to display an image,
wherein the display unit displays an image captured by the image sensor and includes the light-emitting device according to claim 1.

15. Electronic equipment comprising:
a housing provided with a display unit; and
a communication unit provided to the housing and configured to perform external communication,
wherein the display unit includes the light-emitting device according to claim 1.

16. A wearable device comprising:
a display apparatus configured to display an image,
wherein the display apparatus includes the light-emitting device according to claim 1.
